(19) United States
(12) Patent Application Publication
(10) Pub. No.: US 2006/0066236 A1
(43) Pub. Date: Mar. 30, 2006

(54) Electronic apparatus, double-sided display panel and method of manufacturing the double-sided display panel

(75) Inventors: Shinsuke Tanaka, Yamagata-ken (JP); Naoki Yazawa, Yamagata-ken (JP)

Correspondence Address: ARENT FOX PLLC, 1050 CONNECTICUT AVENUE, N.W., SUITE 400, WASHINGTON, DC, 20036, US

(73) Assignee: TOHOKU PIONEER CORPORATION

(21) Appl. No.: 11/216,001

(22) Filed: Sep. 1, 2005

(30) Foreign Application Priority Data
Sep. 24, 2004 (JP) 2004-277012

(51) Int. Cl. H05B 33/06; H05B 33/08; H05B 33/10

(52) U.S. Cl. 313/512; 313/511; 313/505

(57) ABSTRACT

It is an object of the present invention to easily connect lead wire section formed on end portion of support substrate to driving circuit parts or a wiring board. A sealing space for sealing up self-emission element sections and is formed between a pair of support substrates. Lead wires for leading signal wires from the sealing space are formed on at least one of the pair of support substrates. Meanwhile, a signal connection member for connecting signal wires formed on the pair of support substrates is formed between the support substrates. In this way, electric signals can be supplied from one support substrate carrying the lead wires formed thereon to the self-emission element section formed on the other support substrate through the signal connection member.

### BACKGROUND OF THE INVENTION

The present invention relates to a double-sided display panel and a method of manufacturing the same, also relates to an electronic apparatus mounting the double-sided display panel.

The present application claims priority from Japanese Application No. 2004-277012, the disclosure of which is incorporated herein by reference.

In recent years, there have been developed various kinds of self-emission type flat panel display devices such as organic EL (Electroluminescent) display device, PDP (Plasma Display Panel) device, and FED (Field Emission Display) device. These display devices are each formed by arranging self-emission elements on a support substrate so as to form a display unit, and have attracted considerable public attention since they need a small power consumption and can be made thinner than a liquid crystal display which requires a back light.

Moreover, each of these self-emission type flat panel display devices is formed by bonding together two support substrates each having a light emission surface facing outside, so that a double-sided display panel is formed which is capable of displaying picture on both the front side and back side thereof. Japanese Unexamined Patent Application Publication No. 2004-14316 discloses a double-sided display panel consisting of an organic EL display panel. However, since an organic EL display panel becomes deteriorated in its display performance once its organic EL devices formed on its support substrate are exposed to an outside air containing moisture, it is necessary to adopt a sealing structure for shielding the organic EL devices from the outside air. On the other hand, as discussed above in relation to prior art, a pair of support substrates consisting of transparent substrates carrying organic EL devices formed thereon are bonded together through their surfaces on which organic EL devices have been formed, thereby sealing the organic EL devices between the pair of support substrates, thus forming display surfaces facing in mutually opposite directions on the outside surfaces of the two support substrates and thus realizing a double-sided display.

In a self-emission type display device such as an organic EL display device mentioned above, since it is required to connect some driving circuit parts or a wiring board for supplying driving signals to self-emission element section, an actual structure in use is formed in a manner such that signal wires are led from the self-emission element section located within the sealing structure so as to form a lead wire section, thus forming a structure for electrically connecting the lead wire section with a connecting section such as the driving circuit parts or the wiring board.

However, as described above, with regard to a double-sided display panel formed by bonding together two support substrates each carrying a self-emission element section through the surfaces mounting the self-emission element sections, the lead wire sections on two support substrates are bonded to face in different directions in a manner such that the lead wire section on one support substrate will not be overlapped with the lead wire section on the other. As a result, since the lead wire sections are projecting indifferent directions, the total area of an entire display panel becomes larger and thus the display panel requires a larger space for setting the same, hence rendering it impossible to satisfy a space-saving requirement when mounting the display panel into a miniaturized electronic apparatus.

Moreover, in a structure where two lead wire sections are projecting in different directions on two support structures, it is necessary to provide more driving circuit parts or a plurality of wiring boards, or to provide an enlarged wiring board corresponding to the above-mentioned different directions. Consequently, an internal space within an electronic apparatus is excessively occupied by the display panel due to the increased driving circuit parts and the enlarged wiring board, hence rendering it impossible to satisfy a space-saving requirement.

On the other hand, if the lead wire sections to be formed on end portions of support substrates are orientated in the same direction, when one lead wire section is being connected to the driving circuit parts or wiring board, the other lead wire section can cause an interference which makes connecting operation difficult. In particular, since two support substrates are bonded to each other in an extremely narrow interval, it is extremely difficult to carry out an operation of connecting the driving circuit parts or wiring board to lead wire sections formed on the substrate surfaces facing each other.

Besides, since two lead wire sections formed on the respective support substrates are formed on different surfaces facing each other, it is necessary to provide two sets of driving circuit parts or two wiring boards to effect electric connections with the respective lead wire sections, or alternatively, it is necessary to provide a wiring board capable of double-sided connections which is usually extremely expensive, hence causing an increase in the cost of electronic parts. Further, since the two lead wire sections are formed on different surfaces facing each other, it is necessary to carry out several connecting operations such as thermo pressure-bonding to form the electric connections with the respective lead wire sections, hence causing an increase in the manufacturing cost.

### SUMMARY OF THE INVENTION,

The present invention has been accomplished to solve the afore-mentioned problem and it is an object of the present invention to provide an improved double-sided display panel formed by bonding together a pair of support substrates each having a self-emission element section formed on one side thereof and a display surface on the other by taking out light through each support substrate, in a manner such that the display surfaces are facing in mutually opposite directions, followed by forming a sealing space for sealing up the self-emission element sections between the pair of support substrates. Specifically, the present invention is to make it possible to easily connect the lead wire sections formed on the end portions of the support substrates with the driving circuit parts or the wiring board, to save a space required in setting the double-sided display panel or a space required in setting an entire module including the driving circuit parts and the wiring board, and to include connection objects such as the driving circuit parts or the wiring board into one module, thereby reducing the cost of parts and the cost of manufacturing process.

In order to achieve the foregoing objects, a double-sided display panel, a method of manufacturing the same, and an electronic apparatus mounting the double-sided display panel according to the present invention are characterized in the following aspects.

In one aspect of the present invention, there is provided a double-sided display panel formed by bonding together a pair of support substrates each having a self-emission element section formed on one side thereof and a display surface formed on the other by taking out light through each support substrate, in a manner such that the display surfaces are facing in mutually opposite directions, followed by forming a sealing space for sealing up the self-emission element sections between the pair of support substrates. Specifically, lead wires for leading signal wires from the sealing space are formed on at least one of the pair of support substrates, a signal connection member for connecting signal wires formed on the pair of support substrates is formed between the pair of support substrates, so that electric signals can be supplied from one support substrate carrying the lead wires formed thereon to the self-emission element section formed on the other support substrate through the signal connection member.

In another aspect of the present invention, there is provided a method of manufacturing a double-sided display panel formed by bonding together a pair of support substrates each having a self-emission element section formed on one side thereof and a display surface formed on the other by taking out light through each support substrate, in a manner such that the display surfaces are facing in mutually opposite directions, followed by forming a sealing space for sealing up the self-emission element sections between the pair of support substrates. In this method, lead wires for leading signal wires from the sealing space are formed on at least one of the pair of support substrates, a signal connection member for connecting signal wires formed on the pair of support substrates is formed between the support substrates. In particular, when bonding together the two support substrates, the signal connection member is pressure-bonded between the pair of support substrates, in a manner such that electric signals can be supplied from one support substrate carrying the lead wires formed thereon to the self-emission element section formed on the other support substrate through the signal connection member.

### BRIEF DESCRIPTION OF THE DRAWINGS

These and other objects and advantages of the present invention will become clear from the following description with reference to the accompanying drawings, wherein:

FIG. 1 is an explanatory view showing a double-sided display panel and a method of manufacturing the same according to one embodiment of the present invention;

FIG. 2A is a plan view showing an example of a lead wire section according to the embodiment shown in FIG. 1, and FIG. 2B is a sectional view taken along x₁-x₁ line of FIG. 2A;

FIG. 3A is a plan view showing another example of a lead wire section according to the embodiment shown in FIG. 1, and FIG. 3B is a sectional view taken along x₂-x₂ line of FIG. 3A;

FIG. 4 is an explanatory view showing a double-sided display panel according to another embodiment of the present invention.

FIGS. 5A and 5B are explanatory views showing a double-sided display panel according to another embodiment of the present invention;

FIG. 6A is a plan view showing an external structure of a double-sided display panel formed according to one embodiment of the present invention, FIG. 6B is a sectional view taken along Y₁-Y₁ line of FIG. 6A, and FIG. 6C is an end view of the double-sided display panel;

FIG. 7 is an explanatory view schematically showing an example of a signal wiring state of a double-sided display panel according to one embodiment of the present invention;

FIG. 8 is an explanatory view schematically showing an example of a signal wiring state of a double-sided display panel according to one embodiment of the present invention;

FIG. 9 is an explanatory view schematically showing an example of a signal wiring state of a double-sided display panel according to one embodiment of the present invention;

FIG. 10 is an explanatory view schematically showing an example of a signal wiring state of a double-sided display panel according to one embodiment of the present invention;

FIG. 11A is a plan view showing an external structure of a double-sided display panel formed according to another embodiment of the present invention, FIG. 11B is a sectional view taken along Y₂-Y₂ line of FIG. 11A;

FIG. 12 is an explanatory view schematically showing an example of a signal wiring state of a double-sided display panel according to one embodiment of the present invention;

FIG. 13 is an explanatory view schematically showing an example of a signal wiring state of a double-sided display panel according to one embodiment of the present invention; and

FIG. 14 is an explanatory (sectional) view showing an embodiment of a double-sided display panel formed according to the present invention.

### DETAILED DESCRIPTION OF THE PREFERRED EMBODIMENTS

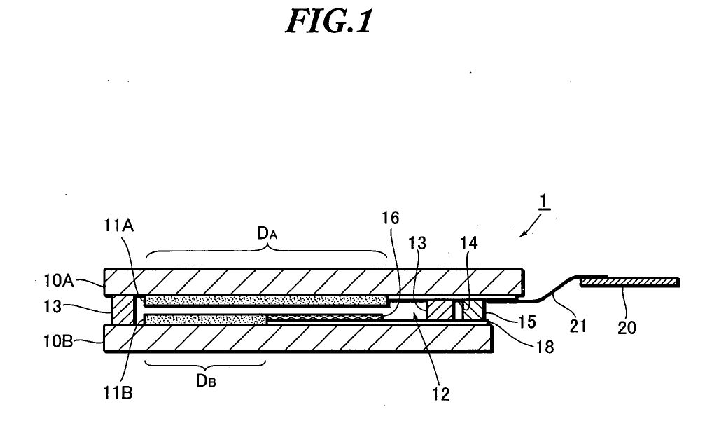

In the following, preferred embodiments of the present invention will be described with reference to the accompanying drawings. FIG. 1 is an explanatory view showing a double-sided display panel 1 and a method of manufacturing the same according to one embodiment of the present invention. As shown, the double-sided display panel 1 is formed in a manner such that each support substrate 10A (10B) is provided with one self-emission element section 11A (11B) on one side thereof, and light is taken out through each support substrate 10A (10B) so that the other side of each support substrate 10A (10B) can act as a display surface D_{A} (D_{B}). The two support substrates 10A and 10B are then bonded together with their display surfaces D_{A} and D_{B} facing in mutually opposite directions, thereby forming a sealing space 12 for sealing the self-emission element sections 11A and 11B between the pair of the support substrates 10A and 10B. In fact, the sealing space 12 is formed by bonding together the support substrates 10A and 10B with a sealing member 13 interposed therebetween, thereby forming an internal space surrounded by the support substrates 10A, 10B and the sealing member 13 formed near the edges of the support substrates 10A and 10B. If necessary, a desiccant 16 can be provided within the sealing space.

Lead wires 14 for leading signal wires from the sealing space 12 are formed on at least one of the two support substrates 10A and 10B, while signal connection member 15 for connecting signal wires formed on the pair of support substrates 10A, 10B is formed between the pair of support substrates 10A and 10B, thereby supplying electric signals through the signal connection member 15 from one support substrate 10A carrying the lead wires 14 formed thereon to the self-emission element section 11B. That is, in the illustrated embodiment, a connecting portion of a flexible wiring board 21 is pressure-bonded to signal wires such as the lead wires 14 formed on the support substrate 10A, so that signals from a circuit board 20 can be supplied through the flexible wiring board 21 to the self-emission element section 11B on the support substrate 10B.

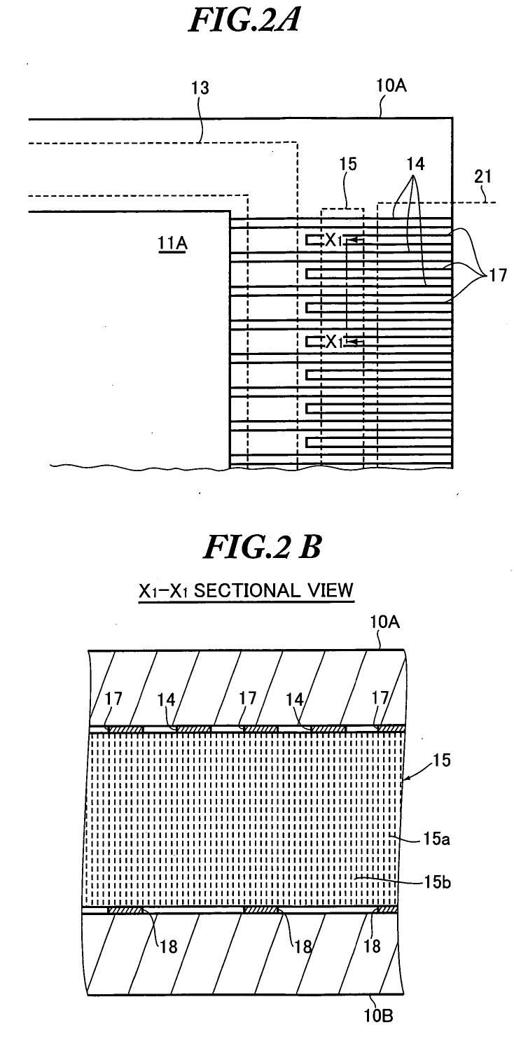

FIG. 2 provides explanatory views showing an example of a lead wire section formed according to the embodiment of FIG. 1 (FIG. 2A is a plan view and FIG. 2B is a sectional view taken along x₁-x₁ line) . In this example, signal wires 17 not conducted with the self-emission element section 11A are formed on the support substrate 10A on which signal wires 14 conducted with the self-emission element section 11A have been formed, while signal wires 17 and the lead wires 18 conducted with the self-emission element section 11B on the support substrate 10B are connected with each other by virtue of the signal connection member 15. In this way, signals supplied from the flexible wiring board 21 can be supplied to the self-emission element section 11A through the lead wires 14, and also from the signal wires 17 to the self-emission element section 11B through the signal connection member 15 and the lead wires 18.

The signal connection member 15, as shown in FIG. 2B, consists of an anisotropic conductive elastic material (in more detail, an anisotropic conductive rubber) formed by arranging and burying a plurality of conductors 15a in a specific direction in an elastic body 15b, and is pressed-bonded between two support substrates 10A and 10B by bonding together the pair of support substrates 10A and 10B, thereby individually effecting connections between the signal wires 17 and the lead wires 18.

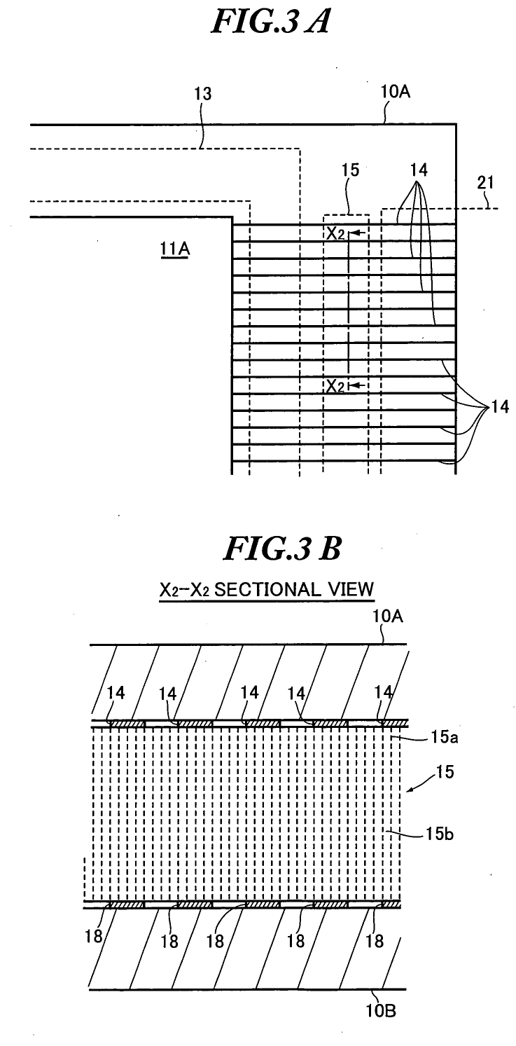

FIG. 3 provides explanatory views showing another example of a lead wire section formed according to the embodiment of FIG. 1 (FIG. 3A is a plan view and FIG. 2B is a sectional view taken along x₂-x₂ line). In this example, signal wires (lead wires 14 and 18) conducted with the respective self-emission element sections are formed on the pair of the support substrates 10A and 10B, and are partially conducted with each other through the signal connection member 15. Namely, the lead wires 14 of the self-emission element section 11A formed on one support substrate 10A are connected with the lead wires 18 of the self-emission element section 11B formed on the other support substrate 10B by way of the signal connection member 15, so that common signals from the flexible wiring board 21 can be supplied to both the two self-emission element sections 11A and 11B.

A method of manufacturing the double-sided display panel 1 according to the present embodiment will be described as follows. Namely, at first, a pretreatment is carried out to form the lead wires 14 and 18 or the signal wires 17 on the respective support substrates 10A and 10B, followed by forming the self-emission element sections 11A and 11B on the respective support substrates 10A and 10B. Afterwards, one or both of the support substrates 10A and 10B are coated with the sealing member 13 in a manner such that the self-emission element sections 11A and 11B are surrounded by the sealing member. Meanwhile, the signal connection member 15 is arranged on the predetermined positions of the support substrates 10A and 10B.

Subsequently, the two support substrates 10A, 10B are bonded to each other to form the sealing space 12 by virtue of the sealing member 13, while the signal connection member 15 is pressure-bonded between the two support substrates 10A, 10B during the bonding, in a manner such that electric signals can be supplied from the support substrate 10A carrying the lead wires 14 formed thereon to the self-emission element section 11B formed on the support substrate 10B through the signal connection member 15.

Using the double-sided display panel 1 formed in the present embodiment, it is possible to perform a double-sided displaying by virtue of the display surfaces D_{A} and D_{B} formed by virtue of the two self-emission element sections 11A and 11B. On the other hand, since the two self-emission element sections 11A and 11B are sealed within the sealing space 12 formed between the support substrates 10A and 10B, it is possible to save space in the thickness direction as compared with an example in which each of the self-emission element sections 11A and 11B is provided with one sealing space.

Further, the lead wires 14 for leading signal wires from the sealing space 12 are formed on at least one of the pair of support substrates 10A and 10B, while the signal connection member 15 connecting the signal wires respectively formed on the pair of support substrates 10A and 10B is formed between the support substrates 10A and 10B, so that electric signals can be supplied from the support substrate 10A carrying the lead wires 14 formed thereon to the self-emission element section 11B formed on the support substrate 10B through the signal connection member 15. Therefore, it is possible to supply signals from one support substrate 10A to the two self-emission element sections 11A and 11B.

In this way, the lead wire sections for supplying signals to the self-emission element sections 11A and 11B are required to be provided in only one support substrate 10A, making it possible to reduce an area occupied by an entire display panel as compared to an example in which two lead wire sections are projecting in different directions. Further, since it is allowed to perform only one operation of pressure-bonding to connect the lead wire sections to the circuit board (as with a display panel having one self-emission element section), it is possible to realize a double-sided display panel which involves only a simplified step of mounting the circuit board and the like. Moreover, since the circuit board and the like to be connected for supplying signals to the two self-emission element sections 11A and 11B can be made into an integral body, it becomes possible to reduce the cost of parts and to reduce an area occupied for setting a display panel containing mounted parts such as circuit board. In addition, since it is allowed to carry out only one step for connecting circuit board to the lead wire sections, it is possible to reduce the cost of manufacturing process and realize an increased productivity.

Specifically, as shown in FIG. 3, when signal wires (lead wires 14, 18) conducted with the self-emission element sections 11A, 11B are formed on the pair of the support substrates 10A, 10B and part of the lead wires 14, 18 are connected with each other through the signal connection member 15, signals supplied from single one circuit board or the like can be supplied to both the self-emission element sections 11A and 11B, thereby making it possible to display mutually related contents on the two display surfaces D_{A} and D_{B} with a high reliability.

Furthermore, as the signal connection member 15 it is allowed to use an anisotropic conductive elastic member formed by aligning a plurality of conductors 15a in a specific direction and burying the same in an elastic body 15b. Then, when the pair of the support substrates 10A and 10B are bonded to each other, it is allowed to use a bonding-together step to form a sealing space 12, thereby making it possible to pressure-bond the signal connection member 15 in position, thus effecting an easy attachment of the signal connection member 15 without increasing other steps.

Preferably, part of the conductor 15a in the signal connection member 15 mentioned above or one of the foregoing signal wires is formed of gold (Au). By using gold, contact resistance can be reduced, and it is possible to ensure the desired connection without being affected by secular change. Further, as to the signal wires, it is also possible to use a material formed by laminating a low-resistant metal or an alloy such as chromium on ITO. Besides, since an adhesion between ITO and gold is not so satisfactory, it is preferable to interpose a nickel film between ITO and gold film when laminating gold on ITO.

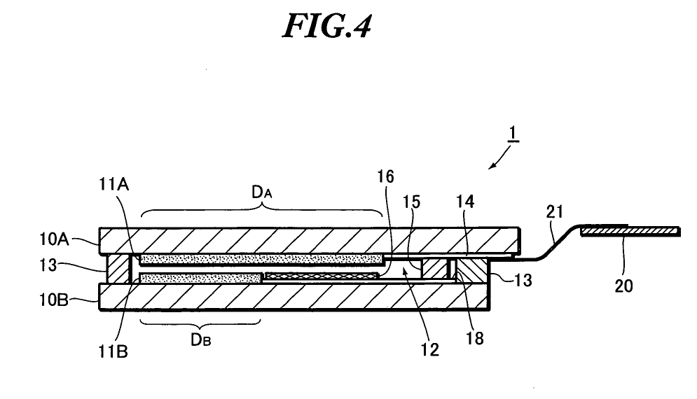

FIG. 4 is an explanatory view showing a double-sided display panel formed according to another embodiment of the present invention (some elements which are the same as those in the above-described embodiment are represented by the same reference numerals and the same description will be partially omitted). In this embodiment, the signal connection member 15 is arranged in the sealing space 12. Accordingly, in addition to the above-described advantages, since it is possible for the sealing space 12 to contain almost no moisture and oxygen, it is almost not necessary to worry about a corrosion and an oxidation of the signal connection member 15, thereby realizing a highly reliable conducted state between the two substrates.

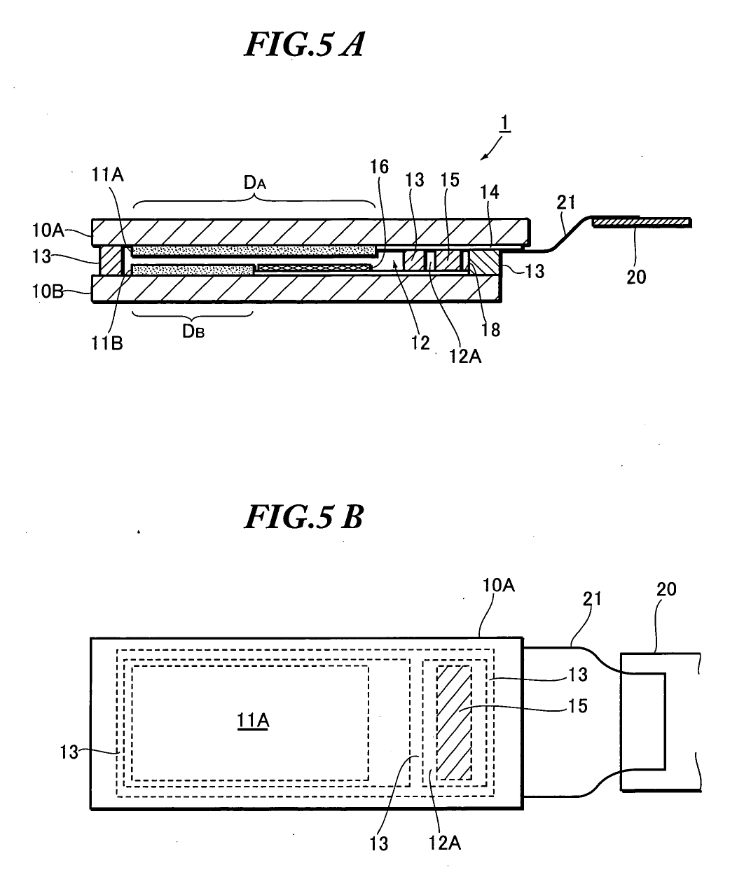

FIG. 5 provides explanatory views showing a double-sided display panel formed according to a further embodiment of the present invention (some elements which are the same as those in the foregoing embodiments are represented by the same reference numerals and the same description will be partially omitted). In this embodiment, the signal connection member 15 is disposed in another sealing space 12A which is not the foregoing sealing space 12. Namely, one more sealing space 12A is formed outside the sealing space 12 by virtue of the sealing member 13, so that the signal connection member 15 can be disposed in the sealing space 12A. In this way, it is possible to seal up the signal connection member 15 so as to prevent it from being corroded and oxidized, and to separate the signal connection member 15 from the self-emission element sections 11A and 11B.

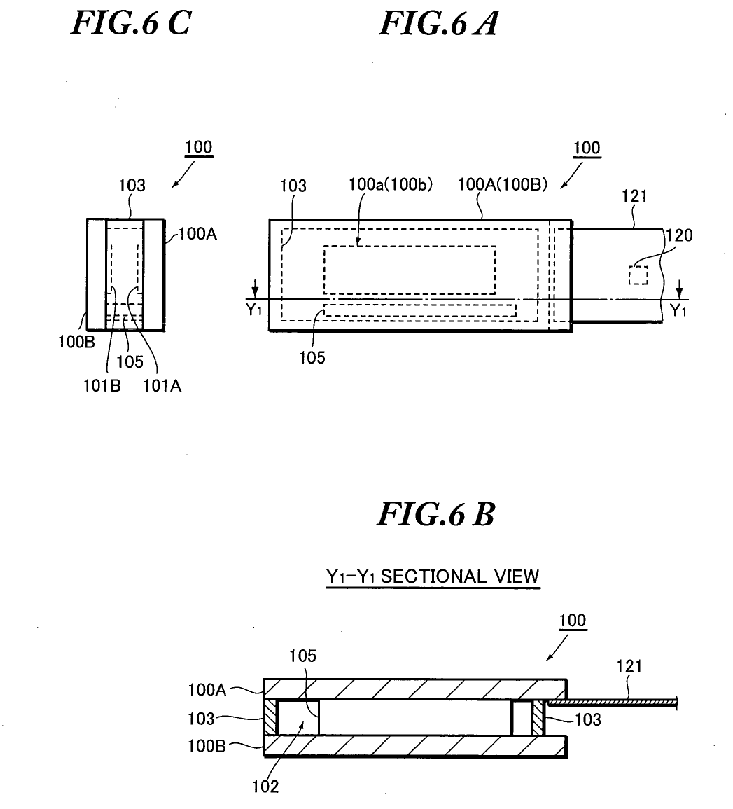

Next, description will be given to explain a more detailed embodiment of the present invention. FIG. 6 provides explanatory views showing an external structure of a double-sided display panel 100 according to the detailed embodiment (FIG. 6A is a plan view, FIG. 6B is a sectional view taken along Y₁-Y₁ line, and FIG. 6C is an end view) . As shown, similar to the foregoing embodiments, the double-sided display panel 100 is formed in a manner such that each support substrate 100A (100B) is provided with one self-emission element section 101A (101B) on one side thereof, and light is taken out through each support substrate 101A (101B) so that the other side of each support substrate 101A (101B) can act as a display surface 100ₐ (100_{B}). The two support substrates 100A and 100B are then bonded together by virtue of a sealing member 103 with the display surfaces 100ₐ, 100_{B} facing in mutually opposite directions, thereby forming a sealing space 102 for sealing the self-emission element sections 101A and 101B between the pair of the support substrates 100A and 100B.

Then, a connecting portion of a flexible wiring board 121 is connected to the support substrate 100A carrying lead wires (not shown) formed thereon, while a signal connection member 105 for connecting signal wires (not shown) formed on the support substrates 100A and 100B is formed between the support substrates 100A and 100B. In this embodiment, the signal connection member 105 is formed along an edge different from the edge of the support substrate 100A connected with the flexible wiring board 121 (the width of the signal connection member 105 is appropriately set in response to signal wires to be connected). However, the present invention should not be limited by this. In fact, it is also possible for the signal connection member 105 to be formed along the edge of the support substrate 100A connected with the flexible wiring board 121 in a manner as described in the foregoing embodiments. Besides, although there has been shown an example in which the signal connection member 105 is formed on the inner side of the sealing member 103, this should not form any limitation to the present invention. Actually, it is also possible for the signal connection member 105 to be formed on the outside of the sealing member 103.

The present embodiment represents COF structure (Chip On Film) in which driver IC chip (semiconductor circuit chip containing driver) is mounted on the flexible wiring board 121, thus forming an arrangement in which the self-emission element sections 101A and 101B are driven by the driver IC chip 120.

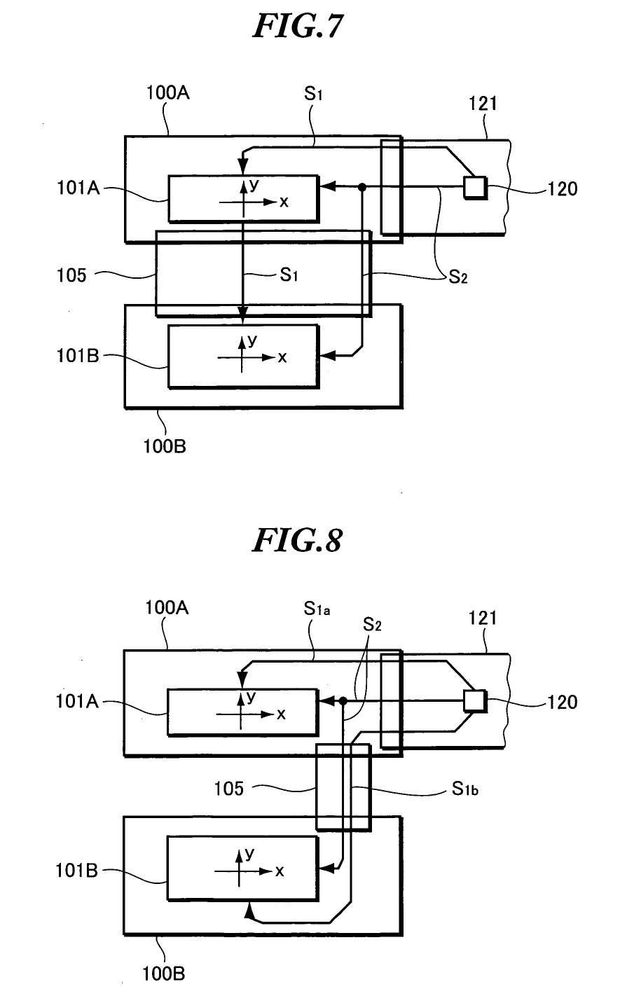

FIG. 7 and FIG. 8 are explanatory views schematically showing examples representing signal wiring state on the double-sided display panel 100 according to the present embodiment. In an example shown in FIG. 7, with respect to the self-emission element section 101A on the support substrate 100A, there have been formed signal wires for supplying data driving signal S₁ from the driver IC chip 120 on the flexible wiring board 121 to the electrodes arranged in x direction. Here, while the data driving signal S₁ is supplied to the self-emission element section 101A through the above-mentioned signal wires, it is also supplied from the self-emission element section 101A to the electrodes arranged in x direction of the self-emission element section 101B on the support substrate 100B, by way of signal wires formed through the signal connection member 105.

Moreover, with respect to the self-emission element section 101A there are formed signal wires for supplying scan selection driving signal S₂ from the driver IC chip 120 to the electrodes arranged in y direction. Actually, the scan selection driving signal S₂ is supplied to the self-emission element section 101A through the foregoing signal wires, and also supplied to the electrodes arranged in y direction of the self-emission element section 101B through the signal wires branching from the foregoing signal wires and passing through the signal connection member 105.

By virtue of the signal wires shown in FIG. 7, it is possible to supply both the data driving signal Si and the scan selection driving signal S₂ (both of which are outputted from one driver IC chip) to the two self-emission element sections 101A and 101B.

FIG. 8 is an explanatory view schematically showing another example representing signal wiring state on the double-sided display panel 100 according to the foregoing embodiment. In this example, with respect to the self-emission element section 101A on the support substrate 100A, there have been formed signal wires for supplying data driving signal S₁ₐ from the driver IC chip 120 on the flexible wiring board 121 to the electrodes arranged in x direction. Meanwhile, with respect to the self-emission element section 101B on the support substrate 100B, there have been formed signal wires for supplying data driving signal S_{1b} through the signal connection member 105 from the driver IC chip 120 to the electrodes arranged in x direction.

Further, with respect to the self-emission element section 101A there are formed signal wires for supplying scan selection driving signal S₂ from the driver IC chip 120 to the electrodes arranged in y direction. Actually, the scan selection driving signal S₂ is supplied to the self-emission element section 101A through the foregoing signal wires, and also supplied to the electrodes arranged in y direction of the self-emission element section 101B through the signal wires branching from the foregoing signal wires and formed through the signal connection member 105.

By virtue of the signal wires shown in FIG. 8, it is possible to supply two sorts of data driving signals S₁ and S₂ (both of which are outputted from one driver IC chip) to the two self-emission element sections 101A and 101B, and to supply a common scan selection driving signal S₂ to the two self-emission element sections 101A and 101B.

FIG. 9 is a modification of the example shown in FIG. 7, representing a COG (Chip On Glass) structure in which one driver IC chip 120 is mounted on the support substrate 100A. In this example, data/scan control signal S₃ is inputted to the driver IC chip 120 through the flexible wiring board 121, while data driving signal S₁ and the scan selection driving signal S₂ are outputted from the driver IC chip 120 in response to the data/scan control signal S3.

In this way, similar to the example shown in FIG. 7, with respect to the self-emission element section 101A there are formed signal wires for supplying data driving signal S₁ from the driver IC chip 120 to the electrodes arranged in x direction. Actually, the data driving signal S₁ is supplied to the self-emission element section 101A through the foregoing signal wires, and also supplied to the electrodes arranged in x direction of the self-emission element section 101B on the support substrate 100B, by way of the signal wires extending from the self-emission element section 101A and passing through the signal connection member 105. Further, with respect to the self-emission element section 101A there are formed signal wires for supplying scan selection driving signal S₂ from the driver IC chip 120 to the electrodes arranged in y direction. Actually, the scan selection driving signal S₂ is supplied to the self-emission element section 101A through the foregoing signal wires, and also supplied to the electrodes arranged in y direction of the self-emission element section 101B, by way of the signal wires branching from the foregoing signal wires and passing through the signal connection member 105.

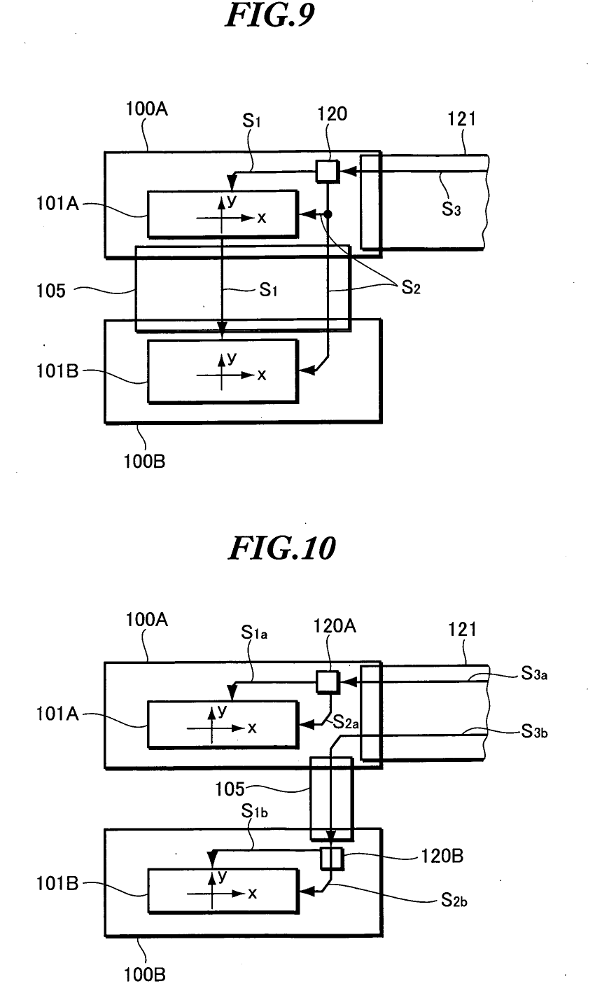

FIG. 10 shows an example of COG in which the driver IC chips 120A and 120B are mounted on the support substrates 100A and 100B. In this way, it is allowed to form signal wires for supplying one data/scan control signal S₃ₐ supplied through the flexible wiring board 121 to the driver IC chip 120A on the support substrate 100A, and to form signal wires for supplying another data/scan control signal S_{3b} through the signal connection member 105 to the driver IC chip 120B on the support substrate 100B. Then, the self-emission element section 101A is driven by the data driving signal S₁ₐ and the scan selection driving signal S₂ₐoutputted from the driver IC chip 120A, while the self-emission element section 101B is driven by the data driving signal S_{1b} and the scan selection driving signal S_{2b} out putted from the driver IC chip 120B.

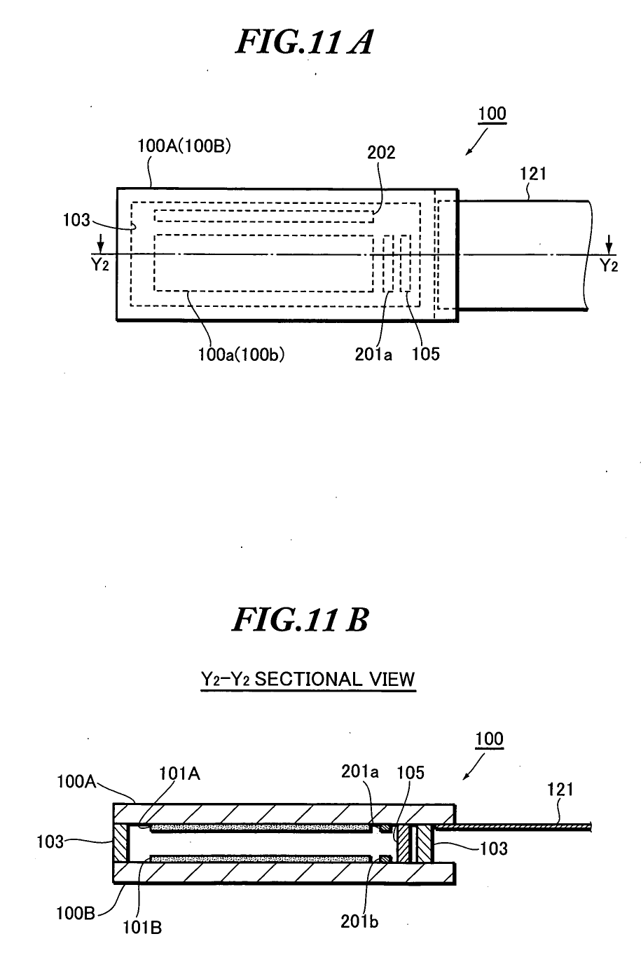

FIG. 11 provides explanatory views (FIG. 11A is a plan view and FIG. 11B is a sectional view taken a long Y2-Y2) showing an external structure of a double-sided display panel formed according to a further embodiment of the present invention (some elements which are the same as those in the foregoing embodiment shown in FIG. 6 are represented by the same reference numerals and the same description will be omitted). In this embodiment, formed on the support substrate 100A on which lead wires have been formed is an electric circuit containing driver (such as the scanning driver 201a and the data driver 202 formed of TFT) for driving the self-emission element section 101A, while an electric circuit (such as the scanning driver 201a formed of TFT) is formed on the support substrate 100B.

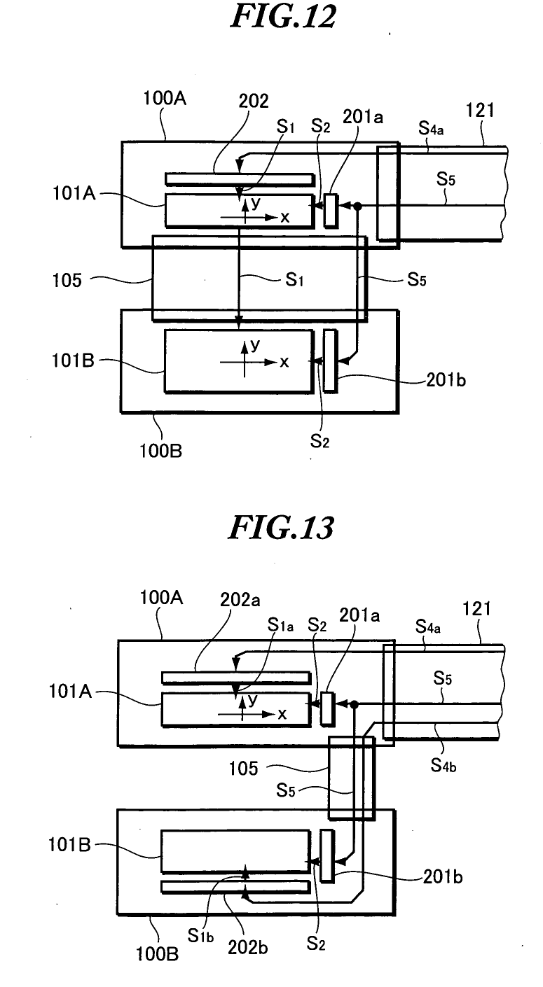

FIG. 12 and FIG. 13 are explanatory views schematically showing examples representing signal wiring state on the double-sided display panel 100 according to the present embodiment. In an example shown in FIG. 12, with respect to the self-emission element section 101A on the support substrate 100A, there have been formed signal wires for supplying data control signal S₄ and scan selection signal S₅ through the flexible wiring board 121, inputting the data control signal S₄ into the data driver 202, and inputting the scan selection signal S₅ into the scan driver 201a. Then, there are formed signal wires for supplying data driving signal S₁ from the data driver 202 to the electrodes arranged in x direction of the self-emission element section 101A, as well as signal wires for supplying scan selection driving signal S₂ from the scanning driver 201a to the electrodes arranged in y direction of the self-emission element section 101A.

On the other hand, the signal wires for supplying the scan selection signal S₅ are branching on the support substrate 101A, and there are formed signal wires for inputting the scan selection signal S₅ to the scanning driver 201b on the support substrate 100B by way of the signal connection member 105. Further, there are formed signal wires for supplying scan selection driving signal S₂ from the scan driver 201b to the electrodes arranged in y direction of the self-emission element section 101B.

Moreover, the data driving signal S₁ is supplied to the self-emission element section 101A through the above-mentioned signal wires, and also supplied to the electrodes arranged in x direction of the self-emission element section 101B on the support substrate 100B, by way of the signal wires extending from the self-emission element section 101A and passing through the signal connection member 105. Then, the self-emission element sections 101A and 101B are driven by the data driving signal S₁ and the scan selection driving signal S₂ outputted from the scan drivers 201a and 201b.

An example shown in FIG. 13 is almost the same as the example shown in FIG. 12, but forming signal wires for independently supplying data driving signal S₁ₐ to the self-emission element section 101A on the support substrate 100A and the data driving signal S_{1b} to the self-emission element section 101B on the support substrate 100B. Namely, there are formed signal wires for inputting the data control signal S₄ₐ supplied through the flexible wiring board 121 to the data driver 202a formed on the support substrate 100A, as well as signal wires for inputting the data control signal S_{4b} (supplied through the flexible wiring board 121 to the support substrate 100A) from the support substrate 100A to the data driver 202b formed on the support substrate 100B by way of the signal connection member 105. In this way, data driving signals S₁ₐ and S_{1b} from the data drivers 202a and 202b are supplied to the self-emission element sections 101A and 101B. Here, as to the scan selection driving signal S₂, it is supplied in the same manner as shown in FIG. 12.

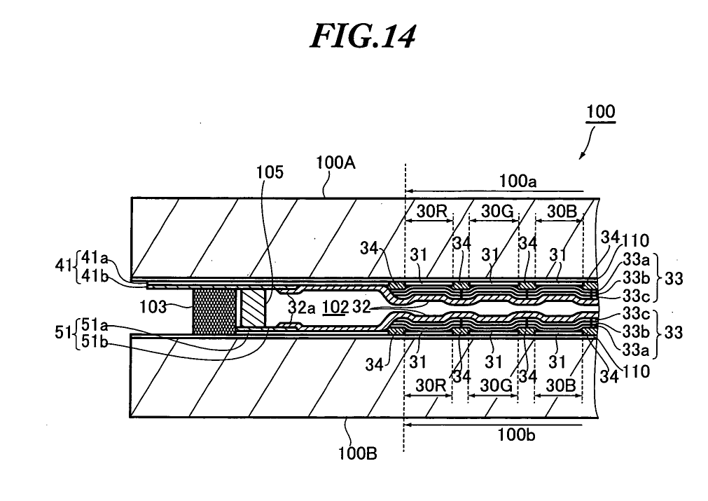

FIG. 14 is an explanatory view (cross sectional view) showing an embodiment of a double-sided display panel 100 formed according to the present invention, in which the self-emission element sections 11A, 11B, 101A, and 101B are each formed by an organic EL device each having at least one organic luminescence functional layer (portions identical with those described above are represented by the same reference numerals and repeated descriptions are partially omitted).

As shown in FIG. 14, the double-sided display panel 100 is formed first by letting the two self-emission element sections face each other and then bonding together the two support substrates 100A and 100B through the sealing member 103, in a manner such that the two display surfaces 100a and 100b formed by virtue of the self-emission element sections consisting of organic EL devices are orientated in mutually opposite directions.

As shown, each self-emission element section are formed by interposing an organic layer 33 containing an organic luminescent layer between first electrodes 31 on one hand and second electrodes 32 on the other, thereby forming a plurality of organic EL devices on the support substrates 100A (100B). In an example shown in FIG. 14, a silicon coating layer 110 is formed on the support substrate 100A (100B), and a plurality of first electrodes 31 consisting of transparent electrode material such as ITO and serving as anodes are formed on the silicon coating layer 110. Further, an insulating film 34 is formed on the first electrodes 31 in a manner such that luminescent areas 30R, 30G, 30B are opened. Then, on the first electrodes 31 in the luminescent areas 30R, 30G, 30B, there are laminated hole transporting layer 33a, luminescent layer 33b, and the electron transporting layer 33c, followed by forming thereon the second electrodes 32 consisting of a metal such as Al or the like which are set as cathodes. Namely, the organic EL devices are formed within the sealing space 102 formed by bonding together the support substrates 100A and 100B through the sealing member 103, thus forming a bottom emission type panel which produces light through the support substrates 100A and 100B.

Then, the end portions 32a of the second electrodes 32 are connected with the lead wires 41 or the signal wires 51 within the sealing space 102. The lead wires 41 or signal wires 51 are such that the first electrode layers 41a and 51a formed by the same material and the same process as the first electrodes 31 are insulated by an insulating layer 34 from the first electrodes 31 and patterned as such, while the second electrode layers 41b and 51b forming low-resistant wiring portions containing gold or silver are formed on the first electrode layers 41a and 51a. Here, although there have been shown self-emission element sections with a prerequisite that they are all driven in a passive driving manner, it is also possible to form self-emission element sections driven in an active driving manner.

The signal connection member 105 connecting the lead wires 41 with the signal wires 51 is pressure-bonded between the support substrates 100A and 100B. In this way, electric signals supplied from a circuit board (not shown) connected with the lead wires 41 on the support substrate 100A can be supplied to the self-emission element section on the support substrate 100B by way of the signal connection member 105.

In such an embodiment, each of the support substrates 100A and 100B is preferred to be a flat plate or a film layer having a transparency and made of glass or plastic.

Although the organic layer 33 is formed by a combination including a hole transporting layer 33a, a luminescent layer 33b, and an electron transporting layer 33c, each of the hole transporting layer 33a, the luminescent layer 33b, and the electron transporting layer 33c may be not only one layer, but also several layers. Moreover, it is also possible to dispense with the hole transporting layer 33a and/or the electron transporting layer 33c. Further, if necessary, it is allowed to insert other organic layers including a hole injection layer, an electron injection layer and a hole blocking layer. Here, the hole transporting layer 33a, the luminescent layer 33b, and the electron transporting layer 33c can be formed by any conventional materials (it is allowed to use either a high molecular material or a low molecular material).

With regard to a luminescent material for forming the luminescent layer 33b, it is allowed to make use of a material presenting a luminescence (fluorescence) when the material returns from a singlet excited state to abase state, or a material presenting a luminescence (phosphorescence) when it returns from a triplet excited state to a base state by way of the singlet excited state.

An adhesive agent forming the sealing member 103 may be a thermal-setting type, a chemical-setting type (2-liquid mixture), or a light (ultraviolet) setting type, which can be formed by an acryl resin, an epoxy resin, a polyester, a polyolefine. Particularly, it is preferable to use an ultraviolet-setting epoxy resin adhesive agent which is quick to solidify without a heating treatment.

Moreover, in the present embodiment, the self-emission element sections consisting of organic EL devices may be a single color display or a multi-color display. In practice, in order to realize a multi-color display, it is allowed to adopt a discriminative painting method or a method in which a single color (white or blue) luminescence functional layer is combined with a color conversion layer formed by a color filter or a fluorescent material (CF manner, CCM manner), a photograph breeching method which realizes a multiple light emission by emitting an electromagnetic wave or the like to the light emission area of a single color luminescent functional layer, or SOLED (transparent Stacked OLED) method in which two or more colors of unit display areas are laminated to form one unit display area.

According to the foregoing embodiments and examples, with regard to a double-sided display panel having a sealing space for sealing up self-emission element sections between a pair of support substrates, it is possible to easily connect lead wire sections formed on the end portions of the support substrates with driving circuit parts or a wiring board, to save a space required in setting the double-sided display panel or a space required in setting an entire module including the driving circuit parts and the wiring board, and to include connection objects such as the driving circuit parts or the wiring board into one module, thereby reducing, the cost of parts and the cost of manufacturing process.

The double-sided display panels according to the above-described embodiments or examples can be installed in portable information terminals such as cellular phone and PDA (Personal Digital Assistant), as well as in electronic apparatus including various display devices, thereby making it possible to reduce the size and weight of electronic apparatuses, thereby realizing a reduced manufacturing cost.

While there has been described what are at present considered to be preferred embodiments of the present invention, it will be understood that various modifications may be made thereto, and it is intended that the appended claims cover all such modifications as fall within the true spirit and scope of the invention.

1. A double-sided display panel formed by bonding together a pair of support substrates each having a self-emission element section formed on one side thereof and a display surface formed on the other by taking out light through each support substrate, in a manner such that the display surfaces are facing in mutually opposite directions, followed by forming a sealing space for sealing up the self-emission element sections between the pair of support substrates,
wherein lead wires for leading signal wires from the sealing space are formed on at least one of the pair of support substrates, a signal connection member for connecting signal wires formed on the pair of support substrates is formed between the pair of support substrates, so that electric signals can be supplied from one support substrate carrying the lead wires formed thereon to the self-emission element section formed on the other support substrate through the signal connection member.

2. The double-sided display panel according to claim 1, wherein signal wires conducted with the respective self-emission element sections are formed on the pair of support substrates, and are partially conducted with each other through the signal connection member.

3. The double-sided display panel according to claim 2, wherein at least part of the signal wires contain gold (Au).

4. The double-sided display panel according to claim 1, wherein the signal connection member consists of an anisotropic and electrically conductive elastic member, which is formed by aligning a plurality of electrically conductive members in a specific direction and burying the same in an elastic material, and is pressure-bonded between the two support substrates by bonding together the pair of support substrates.

5. The double-sided display panel according to claim 4, wherein at least part of the electrically conductive members contain gold (Au).

6. The double-sided display panel according to claim 1, wherein the signal connection member is disposed within the sealing space.

7. The double-sided display panel according to claim 1, wherein the signal connection member is disposed within another sealing space which is not said sealing space.

8. The double-sided display panel according to claim 1, wherein a semiconductor circuit chip containing a driver for driving the self-emission element sections is mounted directly or through a wiring board on the support substrate carrying the lead wires formed thereon.

9. The double-sided display panel according to claim 1, wherein an electric circuit containing a driver for driving the self-emission element sections is mounted on the support substrate carrying the lead wires formed thereon.

10. The double-sided display panel according to claim 1, wherein the self-emission element sections are formed by organic EL devices each having at least one organic luminescent functional layer.

11. An electronic apparatus mounting a double-sided display panel according to any one of claims 1 to 10 or 13 to 16.

12. A method of manufacturing a double-sided display panel formed by bonding together a pair of support substrates each having a self-emission element section formed on one side thereof and a display surface formed on the other by taking out light through each support substrate, in a manner such that the display surfaces are facing in mutually opposite directions, followed by forming a sealing space for sealing up the self-emission element sections between the pair of support substrates,
wherein lead wires for leading signal wires from the sealing space are formed on at least one of the pair of support substrates, a signal connection member for connecting signal wires formed on the pair of support substrates is formed between the support substrates,
wherein when bonding together the two support substrates, the signal connection member is pressure-bonded between the pair of support substrates, in a manner such that electric signals can be supplied from one support substrate carrying the lead wires formed thereon to the self-emission element section formed on the other support substrate through the signal connection member.

13. The double-sided display panel according to claim 2, wherein the signal connection member consists of an anisotropic and electrically conductive elastic member, which is formed by aligning a plurality of electrically conductive members in a specific direction and burying the same in an elastic material, and is pressure-bonded between the two support substrates by bonding together the pair of support substrates.

14. The double-sided display panel according to claim 3, wherein the signal connection member consists of an anisotropic and electrically conductive elastic member, which is formed by aligning a plurality of electrically conductive members in a specific direction and burying the same in an elastic material, and is pressure-bonded between the two support substrates by bonding together the pair of support substrates.

15. The double-sided display panel according to claim 13, wherein at least part of the electrically conductive members contain gold (Au).

16. The double-sided display panel according to claim 14, wherein at least part of the electrically conductive members contain gold (Au).
